(19) United States
(12) Patent Application Publication
(10) Pub. No.: US 2003/0101406 A1
(43) Pub. Date: May 29, 2003

(54) Low complexity and low power FEC supporting high speed parallel decoding of syndrome-based FEC codes

(76) Inventor: Leilei Song, Eatontown, NJ (US)

Correspondence Address: Ryan, Mason & Lewis, LLP, Suite 205, 1300 Post Road, Fairfield, CT, 06430, US

(21) Appl. No.: 09/976,731

(22) Filed: Oct. 12, 2001

(51) Int. Cl. H03M 13/00

(52) U.S. Cl. 714/774

(57) ABSTRACT

Methods and apparatus are disclosed for reducing power consumption and complexity when performing Forward Error Correction (FEC) through parallel decoding techniques. In particular, techniques are described for reducing power consumption and complexity of Reed-Solomon (RS) FEC decoding that is performed in a parallel manner. Steps are taken to reduce power consumption in a FEC decoder when an actual number of errors is less than a maximum error correction capability of the FEC code and when there are no errors. Power is also reduced through limiting hardware complexity of a parallel implementation of a FEC decoder. Hardware sharing is used to reduce overall complexity. A low complexity scheme is used to determine uncorrectable errors in an example RS(255,239) code. In addition, a low complexity encoder is disclosed that converts input symbols to an appropriate format for a particular symbol encoding technique.

### CROSS REFERENCE TO RELATED APPLICATIONS

This application is related to United States Patent Application entitled “High Speed Syndrome-Based FEC Encoder and Decoder and System Using Same,” Attorney Docket Number Dohmen 9-1-4-9, filed contemporaneously herewith in the name of inventors R. Dohmen, T. Schuering, L. Song, and M. Yu and incorporated by reference herein.

### FIELD OF THE INVENTION

The present invention relates generally to digital error correction, and more particularly, to methods and apparatus for low complexity and low power Forward Error Correction (FEC) when performing parallel decoding of syndrome-based FEC codes.

### BACKGROUND OF THE INVENTION

Forward Error Correction (FEC) codes are commonly used in a wide variety of communication systems. For example, such codes can be used in optical communication systems to provide significant power gains within the overall optical power budget of an optical communication link. At the same time, FEC codes lower the Bit Error Rate (BER) of the optical communication link. The resulting gain obtained through the use of the FEC technique can be exploited for either increasing the repeater distances, relaxing optical components and line fiber specifications, or improving the overall quality of communication. For optical communication systems, a high rate error correction code is desirable, as long as the code has large coding gain and can correct both random and burst errors.

One particularly important FEC code is a Reed-Solomon (RS) code. RS codes are maximum distance separable codes, which means that code vectors are maximally separated in a multi-dimensional space. The maximum distance separable property and symbol-level encoding and decoding of an RS code make it an excellent candidate for correcting both random and burst errors. For example, an eight-byte error correcting RS code is recommended as a strong FEC solution for some optical submarine systems. This is due to not only the good random and burst error correcting capability of this code, but also the availability of relatively low complexity encoding and decoding algorithms. Components for RS codes are readily available for throughput rates below one Gigabits per second (Gb/s). However, as the data rate increases to 10 Gb/s and beyond, increases in complexity and power consumption of these FEC devices are the main barriers to integrating them into optical communication systems at relatively low cost.

A need therefore exists for techniques that allow high speed FEC and yet offer relatively low power consumption.

### SUMMARY OF THE INVENTION

Generally, methods and apparatus are disclosed for reducing complexity and power consumption when performing Forward Error Correction (FEC) using parallel syndrome decoding techniques.

In one aspect of the invention, steps are taken to reduce power consumption in a parallel decoder when an actual number of errors is less than a maximum error correction capability of the FEC code. If the number of errors is less than a maximum error correction capability, additional cycles taken by the decoder are superfluous. The power consumption is reduced in and illustrative embodiment by inputting a predetermined logic value into registers of the parallel decoder, which limits switching power. Optionally, clock gating may also be performed to further reduce power.

In another aspect of the invention, steps are taken to reduce power consumption in a parallel decoder when there are no errors. If there are no errors, as defined by a number of syndromes each being a particular value, then a key equation solving device is not started.

In a third aspect of the invention, power is reduced through limiting the hardware complexity of a parallel implementation of a FEC decoder, yet speed of decoding is maintained. Hardware complexity is reduced through various techniques, such as performing polynomial calculation in parallel when determining a key equation. However, certain additional calculations during this process are performed in parallel, which allows a control circuit to select an appropriate one of these calculations during a single cycle. This keeps the decoding speed high.

In a fourth aspect of the invention, hardware sharing is used to reduce overall complexity in a parallel decoder, such as providing one key equation solving device for multiple syndrome generators.

In a fifth aspect of the invention, a low complexity scheme is used to determine uncorrectable errors in an example RS(255,239) code. This scheme further reduces hardware complexity.

In a sixth aspect of the invention, an encoder delays, for a cycle, one of three received symbols. The delayed symbol is preferably the last received symbol. During a first cycle of a three-parallel encoder, a zero is input as the most significant symbol. During additional cycles, the delayed symbol is used as the most significant symbol. Additionally, the two other received symbols are also input into the three-parallel encoder during the first cycle, as the second and least significant symbols. The encoder thus converts the input symbols into a form suitable for parallel encoding. The two received signals are also delayed one cycle, which means that all three received symbols are passed through the encoder after one cycle. After a predetermined number of cycles, redundant symbols are read out of the encoder.

A more complete understanding of the present invention, as well as further features and advantages of the present invention, will be obtained by reference to the following detailed description and drawings.

### BRIEF DESCRIPTION OF THE DRAWINGS

FIG. 1 is a block diagram of a prior art serial Reed-Solomon (RS) (255,239) encoder;

FIG. 2 is a block diagram of a prior art general RS decoder;

FIG. 3 is a block diagram of a prior art serial implementation of one syndrome generator for an RS(255, 239) code;

FIG. 4 is a block diagram of a three-parallel implementation of one syndrome generator block for an RS(255,239) code, in accordance with a preferred embodiment of the invention;

FIG. 5 is a block diagram of a prior art circuit for evaluating error locator polynomials Λ0(x) and Λ1(x) at x=αⁱ;

FIG. 6 is a block diagram of a prior art circuit for evaluating the error evaluator polynomial Ω(x) at x=αⁱ;

FIG. 7 is a two-dimensional data flow graph of a prior art modified Euclidean algorithm;

FIG. 8 is a block diagram of a prior art serial-in serial-out implementation of the modified Euclidean algorithm;

FIG. 9 is a block diagram of a parallel implementation of the modified Euclidean algorithm, in accordance with a preferred embodiment of the invention;

FIG. 10(a) is a block diagram of a three-parallel RS encoder, in accordance with a preferred embodiment of the invention;

FIG. 10(b) is a block diagram of a conversion circuit for converting incoming data, in accordance with a preferred embodiment of the invention;

FIG. 11 is a block diagram of three-parallel RS decoder, in accordance with a preferred embodiment of the invention;

FIG. 12 is a block diagram of a system for detecting uncorrectable errors in an RS(255,239) code, in accordance with a preferred embodiment of the invention;

FIGS. 13(a) and 13(b) show syndrome generators that compute one syndrome for one received block and four syndromes for four interleaved blocks, respectively, in accordance with a preferred embodiment of the invention;

FIG. 14 is a block diagram of input data format in a 64-way interleaved mode, in accordance with a preferred embodiment of the invention;

FIG. 15 is a block diagram of one decoder slice for an RS decoder, in accordance with a preferred embodiment of the invention; and

FIG. 16 is a block diagram of a delayed error correction block, in accordance with a preferred embodiment of the invention.

### DETAILED DESCRIPTION

Aspects of the present invention reduce power and complexity in systems using Forward Error Correction (FEC). For Reed-Solomon (RS) codes, in particular, the present invention reduces complexity and power consumption when used with parallel decoding techniques and reduces complexity during encoding.

By way of introducing the techniques of the present invention, conventional encoding and decoding of RS codes will now be described. In particular, with regard to decoding of an RS code, a modified Euclidean algorithm will be described. Problems with conventional RS decoding will also be described. After describing encoding and decoding of RS codes, the power saving and complexity reducing techniques of the present invention will be described.

### RS Codes: Encoding

An RS code is a linear cyclic code and, hence, can be defined by its generator polynomial G(x). RS codes are generally characterized by how many symbols are needed to carry the data and the error correcting symbols, and how many errors the code can correct. This is generally written as (n, k), where n is the total number of symbols, including error correcting symbols and data symbols, and k is the number of data symbols. An (n, k) code will correct t errors, where t=(n−k)/2. Thus, an RS(255,239) code has 255 total symbols, of which 255−239=16 symbols are error correcting symbols and 239 symbols are data symbols. This code will correct t=(255−239)/2, or 8 symbol errors.

The generator polynomial for a t error-correcting RS code over Galois field GF(2^{m}) is chosen such that 2t consecutive powers of α are roots of G(x) as follows:

$$G ( x ) = {\prod }_{i = 0}^{2 t - 1} ( x - {α}^{i} ) , \qquad ( 1 )$$

where α is a root of a binary primitive polynomial p(x) of degree m that generates the extension field GF(2^{m}). All the valid code word polynomials are multiples of G(x).

Suppose that u(x)=uₖ₋₁x^{k-1}+ . . . +u₁x+u₀ is an information polynomial with symbols coming from GF(2^{m}). Then the nonsystematic code word polynomial is as follows:

c(x)=u(x)G(x). (2)

Systematic encoding is generally used, since information symbols appear clearly in the code word. The systematic code word polynomial is as follows:

c(x)=u(x)·x^{n-k}+<u(x)·^{n-k}>_{G(x)}, (3)

where <·>_{G(x)} denotes the remainder polynomial after division by G(x). It is not difficult to verify that the code word polynomial obtained in such a way is a multiple of G(x). Hence, encoding of an RS code involves only polynomial long divisions over GE(2^{m}). A serial RS encoder can be implemented using a linear feedback shift register, which has a throughput rate of one symbol per cycle. This can be sped up by processing multiple symbols per cycle.

The generator polynomial for an RS(255,239) code, which is an important RS code used for optical submarine systems, among other systems, is as follows:

$$\begin{matrix}G ( x ) = {\prod }_{i = 0}^{15} ( x - {α}^{i} ) . & ( 4 ) \\ \begin{matrix}G ( x ) = {x}^{16} + {α}^{120} {x}^{15} + {α}^{104} {x}^{14} + {α}^{107} {x}^{13} + {α}^{109} {x}^{12} + {α}^{102} {x}^{11} + \\ {α}^{161} {x}^{10} + {α}^{76} {x}^{9} + {α}^{3} {x}^{8} + {α}^{91} {x}^{7} + {α}^{191} {x}^{6} + {α}^{147} {x}^{5} + \\ {α}^{169} {x}^{4} + {α}^{182} {x}^{3} + {α}^{194} {x}^{2} + {α}^{225} x + {α}^{120}\end{matrix} & ( 5 )\end{matrix}$$

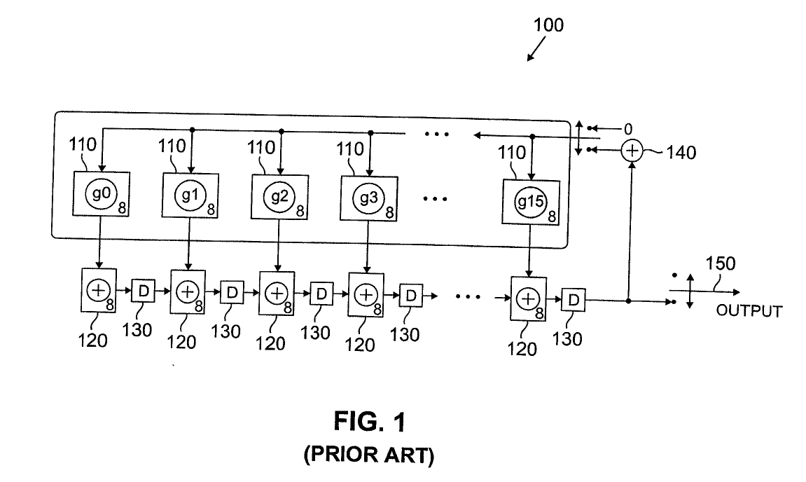

A conventional serial implementation of an RS encoder 100 for an RS(255,239) code is shown in FIG. 1. The RS encoder 100 requires 16 constant coefficient multipliers 110, 16 adders 120 in GF(2⁸), 16 delays 130, an adder 140, and an output 150.

### RS Codes: Decoding

Suppose c(x), r(x) and e(x) are the transmitted code word polynomial, the received polynomial and the error polynomial, respectively, with the relation r(x)=c(x)+e(x). Let Xₗ and Yₗ denote the error locations and error values, respectively, where 1≦l≦t, and Xₗ=αⁱ^{ₗ}.

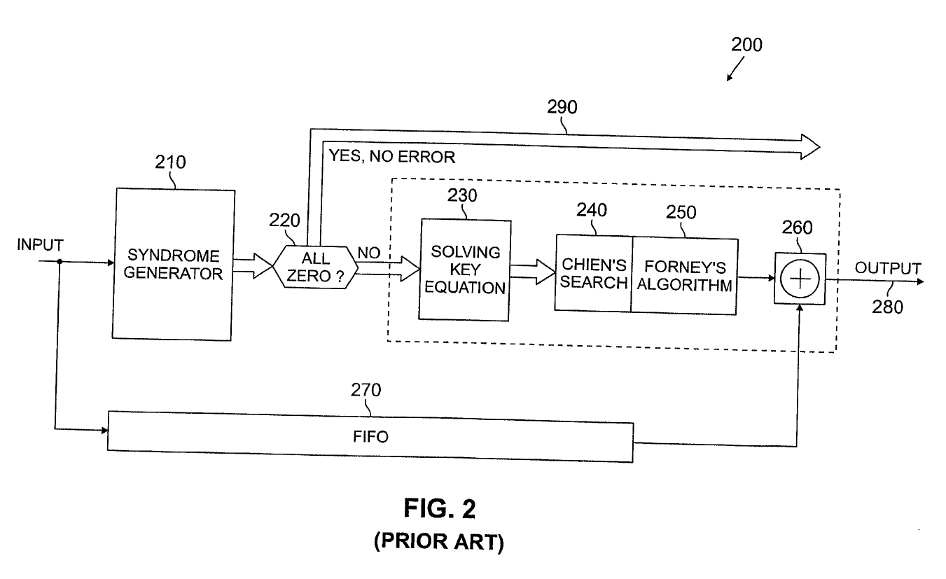

Conventional syndrome-based RS decoding comprises three steps: (i) compute the syndromes; (ii) solve a key equation for the error locator and error evaluator polynomials; and (iii) compute the error locations and error values using Chien's search and Fomey's algorithm. A block diagram of one RS decoder that incorporates these steps is shown in FIG. 2. RS decoder 200 comprises a syndrome generator 210, a test 220, a key equation solving block 230, a Chien's search 240, a Forney's algorithm 250, an adder 260, a First In First Out (FIFO) block 270, and outputs 280 and 290. When data comes in, it passes through the syndrome generator 210, which determines syndromes that are tested in test block 220. If the syndromes are not all zero, they are sent to the key equation solving block 230, then passed through Chien's search 240 and Fomey's algorithm 250. The output of Fomey's algorithm 240 is added, through adder 260, to a delayed version of the input that comes through FIFO 270. Output 280 will be a corrected version of the input. If all the syndromes are zero in test 220, then output 290 is used to signal that there are no errors. The output 280 is ignored under these circumstances.

The syndrome generator block 210 begins, when decoding a t error correcting RS code, by computing the 2t syndromes defined as follows:

$${S}_{j} = r ( {α}^{j} ) = {\sum }_{i = 0}^{n - 1} {{r}_{i} ( {α}^{j} )}^{i} , \qquad ( 6 )$$

for 0≦j≦2t−1. Note that every valid code word polynomial has α⁰, α, . . . , α^{2t-1} as roots and hence the syndromes of each valid code word equal zero. Therefore, the syndromes of the received polynomial can also be written as follows:

$${s}_{j} = e ( {α}^{j} ) = {\sum }_{i = 0}^{n - 1} {{e}_{i} ( {α}^{j} )}^{i} = {\sum }_{l = 1}^{t} {Y}_{l} {X}_{l}^{j} , \qquad ( 7 )$$

which reflects the errors contained in the received polynomial. Define S(x)=S₀+S₁x+ . . . +S₂ₜ₋₁x^{2t-1} as the syndrome polynomial.

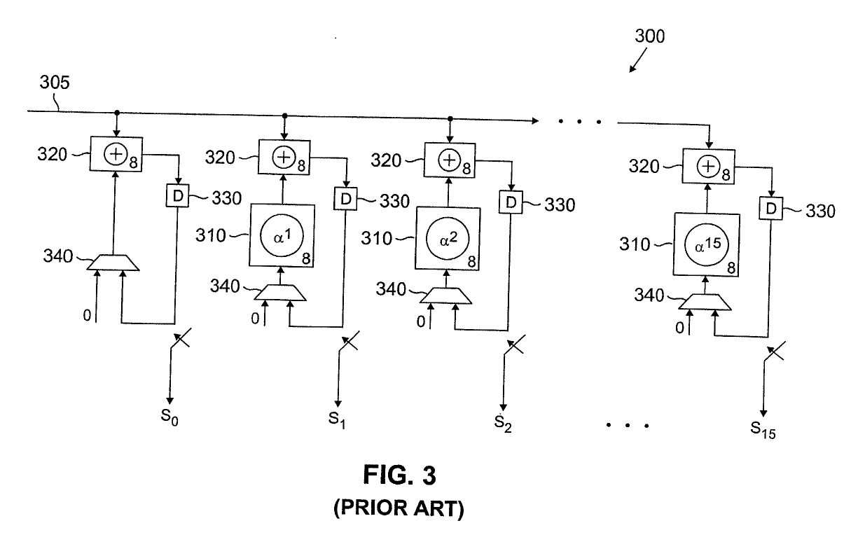

A serial implementation of syndrome computation requires 2t constant multipliers, and has a latency of n clock cycles. A block diagram of a conventional serial implementation of the syndrome generator for an RS(255,239) code is shown in FIG. 3. Syndrome generator 300 comprises an input 305, 15 multipliers 310, which multiply by the constant αⁱ in GF(2⁸), 16 adders 320 in GF(2⁸), 16 delays 330, and 16 multiplexers 340. Multiplexers 340 allow the syndrome generator 300 to be reset every time a symbol from a new block is to be processed. Syndrome generator 300 generates 16 syndromes simultaneously every n clock cycles.

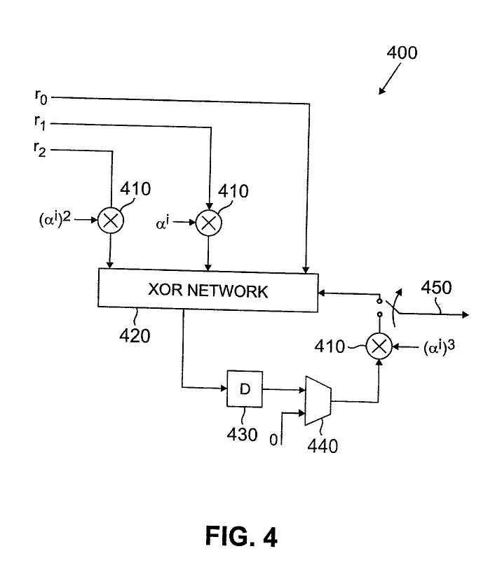

A parallel implementation of a syndrome calculation may also be performed. An l-level parallel implementation processes l received symbols every clock cycle. This type of design speeds up the computation by l times at the expense of an l-fold increase in hardware complexity. For example, a three-parallel architecture for computing the syndrome Sᵢ is shown in FIG. 4, in accordance with a preferred embodiment of the invention. The three-parallel syndrome generator 400 comprises three multipliers 410, an XOR (eXclusive OR) network 420, a delay 430, a multiplexer 440, and an output 450. In a manner similar to multiplexer 340 of FIG. 3, multiplexer 440 allows the syndrome generator 400 to be reset, which is performed every time a new block is to be processed. Output 450 is determined by sampling every n/3 clock cycles.

After the syndromes are computed and if they are not all zero, the second step of RS decoding is to solve a key equation for error polynomials. This occurs in block 230 of FIG. 2. Define an error locator polynomial Λ(x) as the following:

Λ(x)=Π(1−Xₗx), (8)

i.e., Λ(Xₗ⁻¹)=0 for every error location Xₗ. The key equation for RS decoding is defined as the following:

S(x)·Λ(x)=Ω(x)mod x^{2t} (9)

where Ω(x) is an error evaluator polynomial and can be used to compute the error values. The degree of Ω(x) is less than t. Given the syndrome polynomial S(x), the error locator and error evaluator polynomials can be solved simultaneously from Equation (9). Algorithms and architectures for solving the key equation are quite complex.

Once Λ(x) and Ω(x) have been found, an RS decoder can search for the error locations by checking whether Λ(αⁱ)=0 for each i, 1≦i≦n. This occurs in blocks 240 and 250 of FIG. 2. In the case when an error location is found at Xₗ=α⁻ⁱ^{ₗ} (or αⁿ⁻ⁱ^{ₗ} with n=2^{m}−1), the corresponding error value can be calculated using Forney's algorithm as follows:

$${( {Y}_{l} = \frac{Ω ( x )}{x {Λ}^{′} ( x )} \vert )}_{x = {X}_{l}^{( - 1 )} = {α}^{- ij}} , \qquad ( 10 )$$

where Λ′(x) is the formal derivative of Λ(x) and

xΛ′(x)=Λ₁(x)+Λ₃x³+ . . . +Λₜ₋₁x^{t-1} (11)

comprises all of the odd terms of Λ(x). Let Λ0(x) and Λ1(x) denote the polynomials comprising even and odd terms of Λ(x), respectively. Usually, the decoder incrementally evaluates Ω(x), Λ0(x), and Λ1(x) at x=αⁱ for i=1,2, . . . , n, computes the error values, and performs error correction on the (n−i) received symbol before it leaves the decoder. This is the above-noted Chien's search. In other words, Chien's search is used to determine where an error occurs, while Forney's algorithm is used to determine the corresponding error value. This sequential error correction process is summarized as follows, where {cᵢ} is the decoded output sequence:

$$For i = 1 to n$$

$$If ( Λ ( {α}^{1} ) ⩵ 0 ) then$$

$${\hat{c}}_{n - i} = {r}_{n - i} + \frac{Ω ( {α}^{i} )}{Λ1 ( {α}^{i} ) \\}$$

$$End If$$

$$End For$$

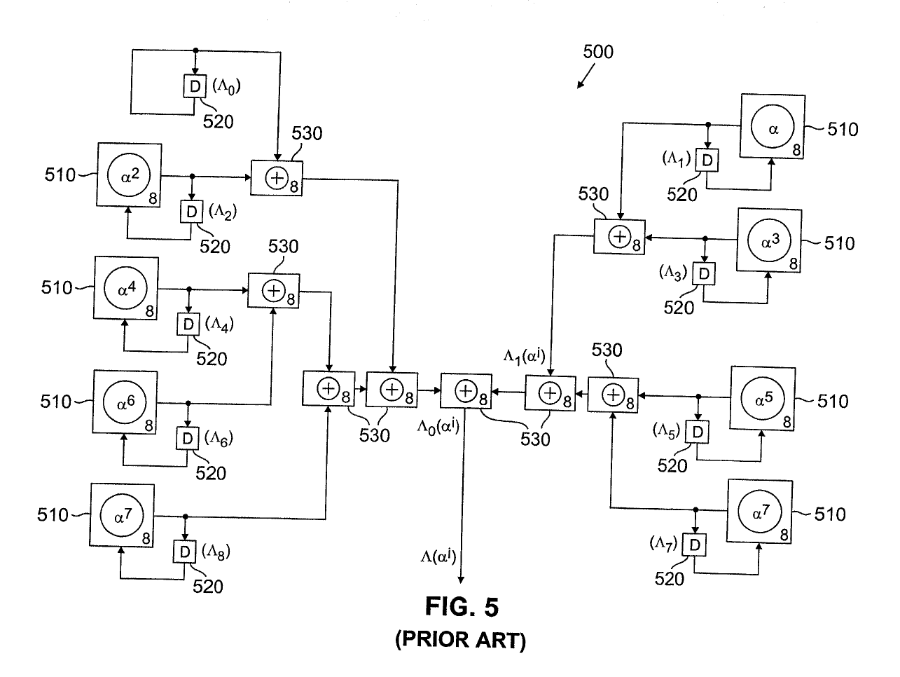

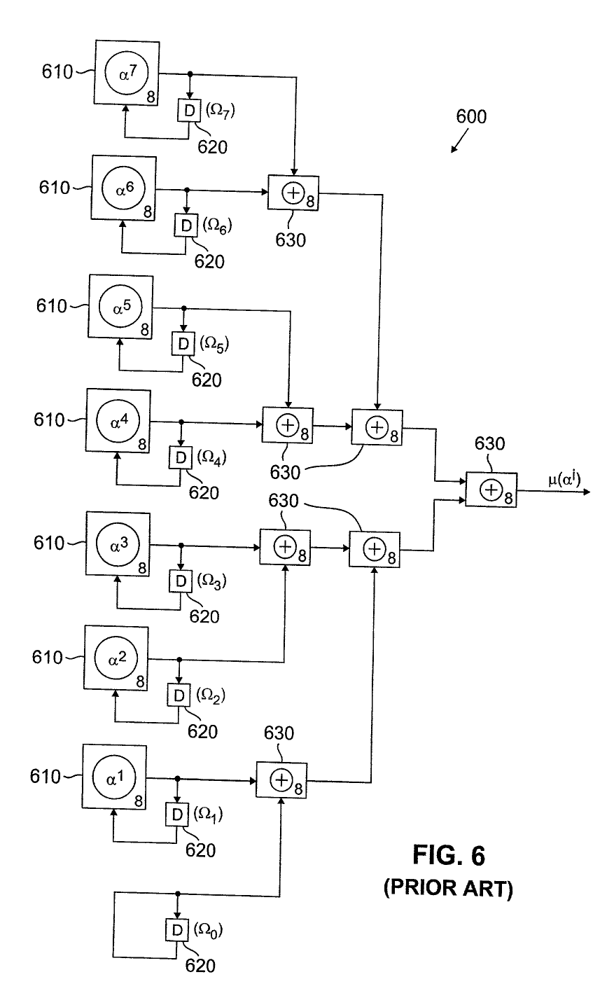

A serial implementation of Chien's search and Formey's algorithm performs error correction on the (n−i) symbol in the i-th clock cycle, for i=1,2, . . . , n. It requires 15 constant multiplications and additions for evaluating Ω(x), Λ0(x), and Λ1(x) at x=αⁱ, as seen in FIGS. 5 and 6. In addition, one Galois field division is required for calculating the error value at the (n−i) location. FIG. 5 shows a circuit 500 for evaluating the error locator polynomial. The circuit comprises a number of constant multipliers 510, a number of D flip flops 520, each having an initial value Λⱼ, and a number of adders 530. FIG. 6 shows a conventional circuit 600 for evaluating the error evaluator polynomial Ω(x) at x=αⁱ. Circuit 600 comprises a number of constant multipliers 610, a number of D flip flops 620, each of which has an initial value Ωⱼ, and a number of adders 630. Inputs to circuits 500 and 600 are those symbols in the brackets next to the registers 520 and 620. The inputs are downloaded from a Euclidean block 900 at the beginning of the Chien's Search. The error locator polynomial Λ(x) is of degree eight, i.e., it has nine coefficient symbols. Hence, there are nine symbol registers in circuit 500. The error evaluator polynomial Ω(x) is of degree seven, i.e., it has eight coefficient symbols. Hence, there are eight symbol registers in circuit 600.

The key equation, Equation (9), can be solved using either Berlekamp-Massey algorithm or the Euclidean algorithm, both of which are well known in the art. Implementations of both of these algorithms are found in Blahut, “Theory and Practice of Error Control Codes,” Addison Wesley (1984), the disclosure of which is incorporated by reference herein. Both of the above-noted algorithms find the error polynomials within 2t iterations and each iteration requires Galois field multiplication and division and has a computation delay of at least one multiplication and one division delay. Consequently, these conventional algorithms are not suitable for high speed implementations.

Fortunately, the division operations in both of the above-noted algorithms can be replaced by multiplications, and the resulting error polynomials are different from those computed using the original algorithms only by a scaling factor, which does not change the computation of error locations and error values. A modified division-free Euclidean algorithm has been proposed for RS decoding. This is described in Shao et al., “VLSI Design of a Pipeline Reed-Solomon Decoder,” IEEE Trans. on Computers, vol. c-34, 393-403, (May 1985), the disclosure of which is incorporated by reference herein. Division-free Berlekamp-Massey algorithms can be found in Shayan et al., “Modified Time-Domain Algorithm for Decoding Reed-Solomon Codes,” IEEE Trans. on Comm., vol. 41, 1036-1038 (1993); and Song et al., “Low-energy software Reed-Solomon Codecs Using Specialized Finite Field Datapath and Division-Free Berlekamp-Massey algorithm,” in Proc. of IEEE International Symposium on Circuits and Systems, Orlando, Fla. (May 1999), the disclosures of which are incorporated by reference herein.

The conventional modified Euclidean algorithm, described below, is more suitable for high speed, low power decoding of RS codes for the following reasons: (1) the loop delay of the modified Euclidean algorithm is half that of the division-free Berlekamp-Masey algorithm; and (2) the division-free Berlekamp-Masey algorithm cannot be terminated earlier even if the actual number of errors is less than t because the computation of discrepancy needs to be carried out for 2t iterations. The latter means that significant power savings, described in more detail below, generally cannot be realized with the Berlekamp-Masey algorithm. Consequently, the Berlekamp-Masey algorithm will not be further described herein.

### RS Codes: Modified Euclidean Algorithm

Originally, the Euclidean algorithm was used to compute the greatest common divisor (GCD) of two polynomials. For RS decoding, the Euclidean algorithm starts with the polynomials S(x) and x^{2t}, and solves the key equation through continuous polynomial division and multiplication. The main idea of the modified Euclidean algorithm is to replace polynomial division by cross multiplications. The algorithm is as follows.

Initially, let R^{(o)}(x)=x^{2t}, Q^{(o)}(x)=S(x), F^{(o)}(x)=0, and G^{(o)}(x)=1. In the r-th iteration, update the polynomials R^{(r+1)}(X), Q^{(r+1)}(x), F^{(r+1)}(X), and G^{(r+1)}(x) as follows. First, calculate

l=deg(R^{(r)}(x))−deg(Q^{(r)}(x)). (12)

Then if l≧0, let

$${E}^{( r )} = [ \begin{matrix}{Q}_{msb} & - {R}_{msb} \cdot {x}^{\vert l \vert} \\ 0 & 1\end{matrix} ] , \qquad ( 13 )$$

else, let

$${E}^{( r )} = [ \begin{matrix}- {Q}_{msb} \cdot {x}^{\vert l \vert} & {R}_{msb} \\ 1 & 0\end{matrix} ] , \qquad ( 14 )$$

where R_{msb} and Q_{msb} are the leading coefficients of R^{(r)}(x) and Q^{(r)}(x), respectively. Next, update the intermediate polynomials using

$$[ \begin{matrix}{R}^{( r + 1 )} \\ {Q}^{( r + 1 )}\end{matrix} ] = {E}^{( r )} \cdot [ \begin{matrix}{R}^{( r )} \\ {Q}^{( r )}\end{matrix} ] ; [ \begin{matrix}{F}^{( r + 1 )} \\ {G}^{( r + 1 )}\end{matrix} ] = {E}^{( r )} \cdot [ \begin{matrix}{F}^{( r )} \\ {G}^{( r )}\end{matrix} ] . \qquad ( 15 )$$

Stop if deg(R^{(r+1)}(x))<t or if deg(Q^{(R+1)}(x))<t. The resulting error polynomials are Λ(x)=F^{(r+1)}(x) and Ω(x)=R^{(r+1)}(x). The computation stops within 2t iterations.

Note that computations in E^{(r)} are cross multiplications. Applying E^{(r)} to R^{(r)}(x) and Q^{(r)}(x) guarantees that the degree of the resulting R^{(r+1)}(x) satisfies

deg(R^{(r+1)}(x))≦max{deg(R^{(r)}(x)),deg(Q^{(r)}(x))}−1,

deg(Q^{(r+1)}(x))=min f{deg(R^{(r)}(x)), deg(Q^{(r)}(x))} (16)

or

deg(R^{(R+1)}(x))+deg(Q^{(r+1)}(X))≦deg(R^{(r)}(x))+deg(Q^{(r)}(x))−1 (17)

Therefore, after 2t iterations, the following results:

$$deg ( {R}^{( 2 t )} ( x ) ) + deg ( {Q}^{( 2 t )} ( x ) ) \leq deg ( {R}^{( 2 t - 1 )} ( x ) ) + deg ( {Q}^{( 2 t - 1 )} ( x ) ) - 1 \leq deg ( {R}^{( 0 )} ( x ) ) + deg ( {Q}^{( 0 )} ( x ) ) - ( 2 t ) = 2 t - 1. \qquad ( 18 )$$

Hence, one of the two polynomials, R^{(2t)}(x) and Q^{(2t)}(x), has degree less than t. This guarantees that the algorithm stops within 2t iterations.

Let

$${E}^{( r )} = {{∐}_{i = 0}}^{r} {E}^{( i )} .$$

Then in each iteration, the following results:

$$[ \begin{matrix}{R}^{( r + 1 )} ( x ) \\ {Q}^{( r + 1 )} ( x )\end{matrix} ] = {E}^{( r )} \cdot [ \begin{matrix}{x}^{2 t} \\ S ( x )\end{matrix} ] ; [ \begin{matrix}{F}^{( r + 1 )} ( x ) \\ {G}^{( r + 1 )} ( x )\end{matrix} ] = {E}^{( r )} \cdot [ \begin{matrix}0 \\ 1\end{matrix} ] , \qquad ( 19 )$$

or

R^{(r+1)}(x)=F^{(r+1)}(x)·S(x)mod x^{2t},

Q^{(r+1)}(x)=G^{(r+1)}(x)·S(x)mod x². (20)

When the number of errors is less than or equal to t, the solution (e.g., the error locator polynomial and the error evaluator polynomial) to the key equation is unique up to a scaling factor. Therefore, the resulting polynomial R^{(2t)}(x) of degree less than t is the error evaluator polynomial, and F^{(2t)}(x) is the error locator polynomial.

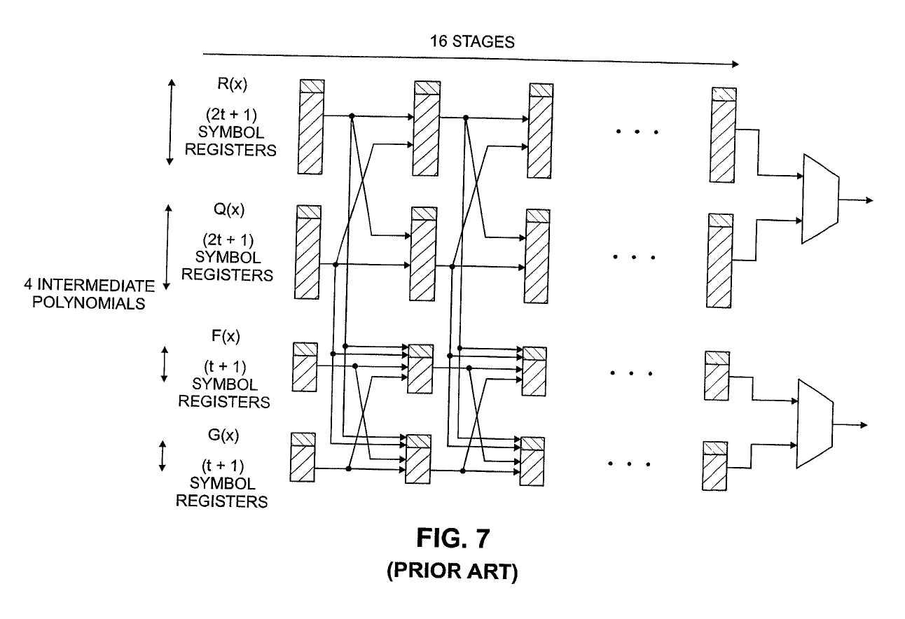

The data dependency in the modified Euclidean algorithm can be illustrated using a two-dimensional data flow graph, as shown in FIG. 7. The two-dimensional data flow graph has a horizontal direction that corresponds to the 2t iterations and a vertical direction that corresponds to the coefficient vectors of the four intermediate polynomials, R(x), Q(x), F(x), and G(x). The two-dimensional data flow graph also corresponds to a complete parallel pipelined implementation of the algorithm that requires (6t+4) registers and (6t+2) Galois field multipliers in each of the 2t pipeline stages. This complete parallel implementation can continuously compute error locator and error evaluator polynomials, and has a latency of 2t cycles and a throughput rate of one set of polynomials per cycle.

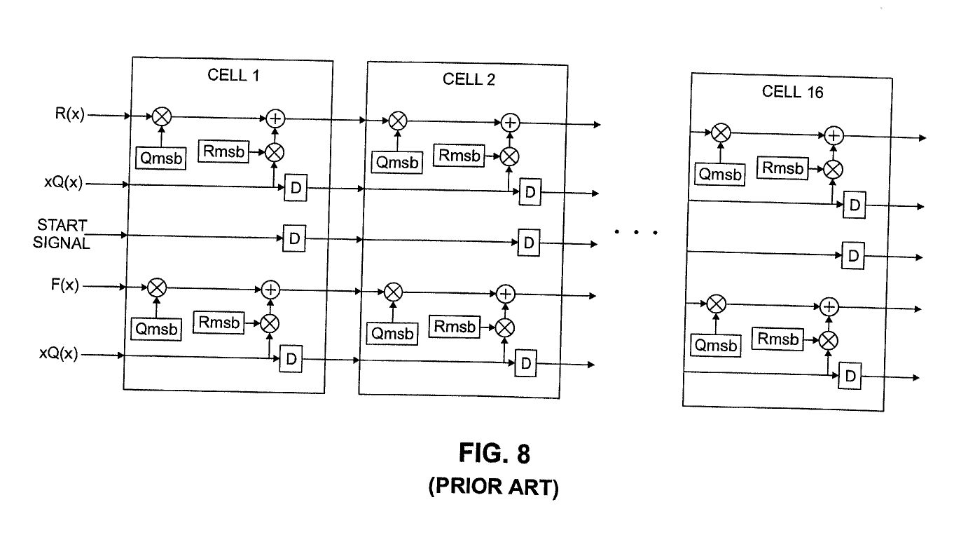

A serial RS decoder requires n cycles to compute the syndromes as well as the Chien's search. This dictates the idea of implementing the modified Euclidean algorithm using a folded architecture that trades throughput rate for area. The 2D array in FIG. 7 can be folded in the direction of the polynomial coefficients, which results in the architecture presented in Shao, incorporated by reference above. A block diagram of this conventional architecture is shown in FIG. 8. This is a serial-in serial-out design, i.e., the syndromes are processed one at a time. The coefficients of the resulting error polynomials are output one at a time after 2t cycles. It contains 2t basic cells, each of which contains four Galois field multipliers.

There are several problems with the design shown in FIG. 8. First, it takes 2t cycles to complete, regardless of how many actual errors there are. Second, there is no way to place the design into a low power mode.

### Low Power and Low Complexity FEC Techniques

The present invention overcomes the above-noted problems with the FIG. 8 decoder by providing a parallel decoder structure that has low power options and that is designed for low complexity. Encoders suitable for use with the present invention will also be described herein.

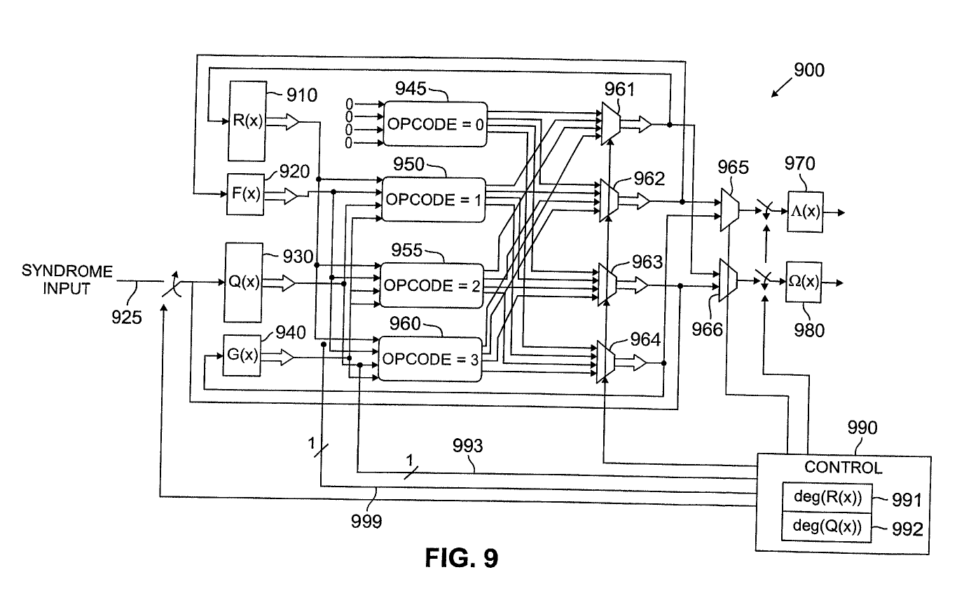

In accordance with one aspect of the present invention, the two-dimensional array in FIG. 7 can be folded along the direction of the 2t stages. This leads to a folded parallel architecture, where the syndromes are processed in parallel during the first iteration, the coefficients of the intermediate polynomials are updated in parallel in the subsequent 2t iterations, and the resulting error polynomials are downloaded in parallel at the end. A variation of the modified Euclidean algorithm using this second folding scheme is shown in FIG. 9.

FIG. 9 illustrates a modified Euclidean algorithm circuit 900. Circuit 900 comprises an R(x) register 910, an F(x) register 920, a syndrome input 925, a Q(x) register 930, a G(x) register 940, opcodes 945, 950, 955, and 960, multiplexers 961, 962, 963, 964, 965, and 966, Λ(x) output 970, Ω(x) output 980, a control circuit 990, and lines 994, 993 that correspond to R_{msb} and Q_{msb}, respectively. Control circuit 990 comprises two registers, deg(R(x)) 991 and deg(Q(x)) 992. Syndrome input 925 periodically latches data into Q(x) register 930 based on a command from control block 990. Control block 990 also controls multiplexers 961 through 966 and latching of output data to Λ(x) output 970 and Ω(x) output 980.

In circuit 900, each iteration carries out one of the following operations:

Opcode=3 (opcode 960 is selected): In this case, both R_{msb} 994 and Q_{msb} 993, the leading coefficients of the R(x) and Q(x) polynomials, are nonzero; and the cross multiplications shown in Equation (15) are carried out to update the four intermediate polynomials.

Opcode=2 (opcode 955 is selected): In this case, R_{msb} 994 equals zero; the variable deg(R(x)), the degree of R(x), is reduced by one. All other intermediate variables remain unchanged.

Opcode=1 (opcode 950 is selected): In this case, Q_{msb} 993 equals zero; only the variable deg(Q(x)), the degree of Q(x), is reduced by one.

Opcode=0 (opcode 945 is selected): This puts the entire block into low power mode by feeding zeros to all the intermediate variables. It is activated upon detection of completion of the key equation solving process, i.e., when either deg(R(x))<t or deg(Q(x))<t is satisfied. The deg(R(x)) 991 and deg(Q(x)) 992 registers are used to determine whether these conditions are met. It should be noted that the register deg(R(x)) 991 may be stored in register R(x) 910 and communicated to control circuit 990. Likewise, register deg(Q(x)) 992 may be stored in register Q(x) 930 and communicated to control circuit 990.

Actual computations are carried out only in “Opcode 3” mode 960, which requires (6t+2) Galois field multipliers. The loop critical path is lower bounded by one multiply-and-add time. Compared with an implementation based on the conventional folding scheme, as shown in FIG. 8, there are multiple advantages of the architecture shown in FIG. 9. First, it processes all syndromes in parallel, and generates all coefficients of the error polynomials in parallel. This interfaces well with the syndrome generator and with the Chien's search block, as shown below in more detail. This also eliminates the need for a parallel-to-serial converter and a serial-to-parallel converter, as required in the conventional folded implementation shown in FIG. 8. Second, when the number of errors that actually occur is smaller than t, i.e., the maximum number of symbol errors that an RS(n, n−2t) code can correct, the Euclidean algorithm converges within less than 2t iterations. A small control circuit 990 is used to detect early convergence of the algorithm (i.e., when either deg(R(x))<t or deg(Q(x))<t is satisfied), download the resulting polynomials, and put the entire block into low power “Opcode=0” mode 945. Under normal operating conditions, the actual number of errors in each block is usually much smaller than t. Consequently, the additional “Opcode=0” mode 945 leads to great power savings.

It should be noted that control circuit 990 operates in parallel with opcodes 945 through 960. As described above, opcodes 945 through 960 operate in parallel with each clock cycle. During this operation, control circuit 990 selects which result of which opcode 945 through 960 is selected by multiplexers 961 through 964 for output by these multiplexers. For example, if both R_{msb} 994 and Q_{msb} 993 are not zero, multiplexers 961 through 964 are adjusted by control circuit 990 to output the result of opcode 960. As another example, if R_{msb}=0, then multiplexers 961 through 964 are adjusted by control circuit 990 to output the result of opcode 955. The conditions under which the results of opcodes 945 and 950 will be selected by control circuit 990 are described above. The benefit of this architecture is that it is faster than a serial implementation. For example, control circuit 990 could examine R_{msb} 994 and Q_{msb} 993 prior to enabling one of the opcodes 945 through 960. However, this type of serial operation will likely not meet timing requirements, as the critical path through circuit 900 will be increased in length and delay.

Additionally, the implementation shown in FIG. 9 also yields complexity benefits because register blocks 920 and 940 are no larger than that necessary to work with their values. The F(x) and G(x) registers will have a complexity on the order of at most t, whereas the system of FIG. 8 for these two values has a complexity of about 2t. This is true because the system of FIG. 8 needs 2t cells, even though F(x) and G(x) will be at most as large as t.

It should be noted that control circuit 990 could also gate clocks going to any circuitry in circuit 900. For instance, there could be flip-flops that switch with each clock cycle. Even though the input, in low power mode, to the flip-flop will be zero, there will be some extra power because of the switching flip flops. This power can be reduced by gating the clocks, as is known in the art.

The modified Euclidean algorithm circuit 900 of the present invention is used in the systems described below, and may be used in other systems.

### Selection of Galois Field Multipliers and Dividers

As is known in the art, there are a variety of different types of Galois field multipliers and dividers. However, not all of these multipliers and dividers are suitable for building low power and high speed RS encoders and decoders. The basic building blocks in RS encoders and decoders include Galois field adders, multipliers and dividers. Addition in GF(2⁸) is straightforward and requires only 8 XOR gates with a computation time of one XOR operation. The performance characteristics of some variable-input multipliers, constant multipliers and dividers over GF(2⁸) and GF((2⁴)²) that are used in conventional RS(255,239) encoder and decoder are summarized as follows.

(1) Variable-input Galois field multipliers using a standard basis representation in GF(2⁸). These are Mastrovito multipliers specifically designed for the primitive polynomial p(X)=X⁸+X⁴+X³+X²⁺1. Mastrovito multipliers are described in Mastrovito, “VLSI Designs for Multiplication over Finite Fields GF(2^{m}).” 6th Int'l Conf. on Applied Algebra, Algebraic Algorithms, and Error-Correcting Codes, 297-309 (July 1988), the disclosure of which is incorporated herein by reference. Each of these multipliers has a complexity of 64 AND gates and 83 XOR gates, and a computation delay of (1D_{AND}+5D_{XOR}), where D_{AND} and D_{XOR} denote the delay of one two-input AND and one two-input XOR gate, respectively.

(2) Variable-input Galois field multipliers using a composite representation in GF((2⁴)²). Each of these multipliers has a complexity of 48 AND gates and 62 XOR gates, and a computation delay of (1D_{AND}+5D_{XOR}). When composite representation is used inside the encoder and/or decoder, a basis conversion circuit containing 18 XOR gates is required to convert each input symbol from the standard basis representation to composite representation, and convert the resulting symbol back to standard basis since code word symbols are in general transmitted in standard-basis representation.

(3) Dedicated constant-coefficient multipliers. For both standard basis and composite basis, a constant-coefficient multiplier requires, on average, 25 XOR gates, and has a delay of 3D_{XOR} on average. For most cases, the constant-coefficient multipliers in composite basis have slightly higher complexity than those in standard basis.

(4) Variable-input dividers. A divider in composite representation containing 107 AND gates and 122 XOR gates is by far the simplest divider circuit for GF(2⁸). It has a computation delay of (3D_{AND}+9D_{XOR}). Two other alternatives for division in GF(2⁸) are to use (i) a standard-basis divider or (ii) a table lookup method with a Read-Only Memory (ROM) of size 256-byte for inversion followed by a variable-input multiplier. The hardware complexity of a standard-basis divider is more than three times that of the composite divider. The ROM-based approach has almost the same complexity for inversion. However, it requires additional multiplication and also consumes more power than the composite-basis divider.

As can be seen, it is advantageous to use composite basis for variable-input multiplications and divisions, while standard basis is preferred for constant-coefficient multiplications. Either of these bases or even mixed use of these two for RS encoders and decoders are possible, depending on the percentage of variable-input multiplications, divisions and constant-coefficient multiplications that are required.

### An Exemplary Encoder and Decoder

This section describes an exemplary architectural design and implementation result of an RS encoder and decoder in accordance with the invention for a 40 Gb/s Synchronous Optical NETwork (SONET) system. In order to achieve 40 Gb/s data throughput rate, a clock frequency of 334 MegaHertz (MHz) would be required for serial encoding and decoding of a 16-way interleaved RS(255,239) code over GF(2⁸). Instead of serial encoding and decoding at such a high operating clock speed, both the encoder and decoder in the present invention process three symbols per code block per cycle and operate at a clock rate of 111 MHz.

The encoding procedure for three-parallel RS(255, 239) code can be derived from Equation (3) as follows. Let G(x) be the generator polynomial shown in Equation (5). Since 239 is not a multiple of three, it is assumed that there is a zero padded at the beginning of each information block. Then the three-parallel RS encoding, starting from the higher order symbols, can be performed as shown below:

$$\begin{matrix}U ( x ) \cdot {x}^{16} mod G ( x ) = \{ [ ⋯ \{ [ 0 \cdot {x}^{18} + {u}_{238} \cdot {x}^{17} + {u}_{237} \cdot {x}^{16} ) mod {G ( x )}_{0} ] \cdot \\ {x}^{3} + ( {u}_{236} \cdot {x}^{18} + {u}_{235} \cdot {x}^{17} + \\ {u}_{234} \cdot {x}^{16} ) mod {G ( x )}_{1} \} \cdot {x}^{3} + ⋯ ] \cdot \\ {x}^{3} + ( {u}_{2} \cdot {x}^{18} + {u}_{1} \cdot {x}^{17} + {u}_{0} \cdot {x}^{16} ) mod {G ( x )}_{79}\end{matrix} \qquad ( 25 )$$

where the underlined computations are carried out in the i-th cycle, for 0≦i≦79. Define the following polynomials:

$$\begin{matrix}{g}_{0} ( x ) = {x}^{16} mod G ( x ) \\ {g}_{0} ( x ) = \begin{matrix} {α}^{120} {x}^{15} + {α}^{104} {x}^{14} + {α}^{107} {x}^{13} + {α}^{109} {x}^{12} + {α}^{102} {x}^{11} + \\ {α}^{161} {x}^{10} + {α}^{76} {x}^{9} + {α}^{3} {x}^{8} + {α}^{91} {x}^{7} + {α}^{191} {x}^{6} + {α}^{147} {x}^{5} + \\ {α}^{169} {x}^{4} + {α}^{182} {x}^{3} + {α}^{194} {x}^{2} + {α}^{225} x + {α}^{120}\end{matrix} & ( 26 ) \\ {g}_{1} ( x ) = {x}^{17} mod G ( x ) \\ {g}_{1} ( x ) = \begin{matrix} {α}^{138} {x}^{15} + {α}^{229} {x}^{14} + {α}^{18} {x}^{13} + {α}^{114} {x}^{12} + {α}^{92} {x}^{11} + \\ {α}^{28} {x}^{10} + {α}^{31} {x}^{9} + {α}^{126} {x}^{8} + {α}^{223} {x}^{7} + {α}^{10} {x}^{6} + {α}^{53} {x}^{5} + \\ {α}^{240} {x}^{4} + {α}^{100} {x}^{3} + {α}^{173} {x}^{2} + {α}^{156} x + {α}^{240}\end{matrix} & ( 27 ) \\ {g}_{2} ( x ) = {x}^{18} mod G ( x ) \\ \begin{matrix}{g}_{2} ( x ) = {α}^{155} {x}^{15} + {α}^{32} {x}^{14} + {α}^{170} {x}^{13} + {α}^{251} {x}^{12} + {α}^{106} {x}^{11} + \\ {α}^{130} {x}^{10} + {α}^{46} {x}^{9} + {α}^{160} {x}^{8} + {α}^{199} {x}^{7} + {α}^{63} {x}^{6} + \\ {α}^{16} {x}^{5} + {α}^{50} {x}^{4} + {α}^{226} {x}^{3} + {α}^{251} {x}^{2} + {α}^{168} x + {α}^{3}\end{matrix} & ( 28 )\end{matrix}$$

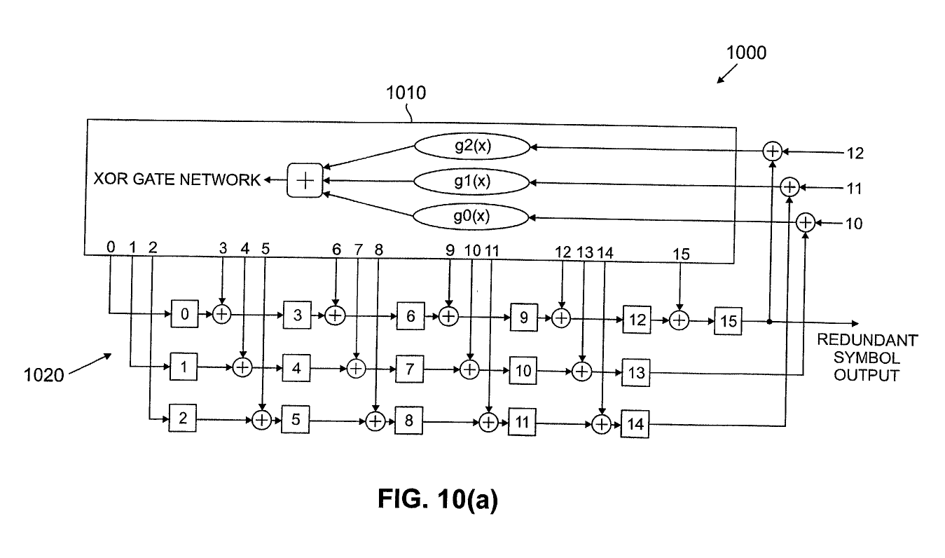

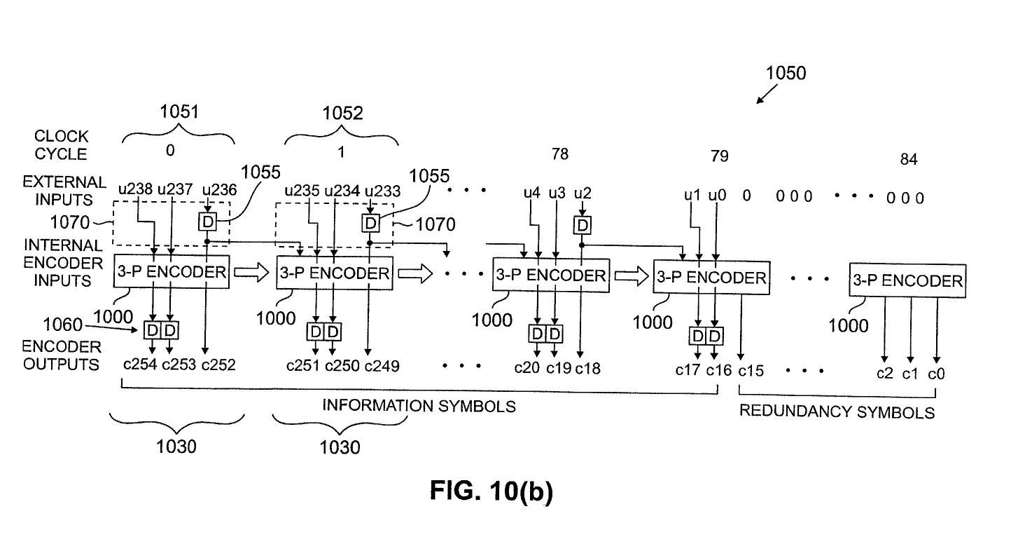

A block diagram of one three-parallel RS encoder 1000 is shown in FIG. 10(a). The circuit of FIG. 10(a) implements Equation (25) by using Equations (26), (27), and (28), and the constant multipliers in these equations are hardwired into an XOR network 1010. In FIG. 10(a), it can be seen that three input symbols, I₀, I₁, and I₂, are input to the RS encoder 1000. These input symbols, I₀, I₁, and I₂, are multiplied by the appropriate polynomials, g₀(x), g₁(x), and g₂(x), respectively, in the XOR network 1010, and the additions shown by reference numeral 1020 are performed. For example, the content of registers is added to the content at location 3 from the XOR network 1010 and the result is placed in register₃. Similarly, the content of register₃ is added to the content at location 6 from the XOR network 1010 and the result is placed in register₆.

As the incoming data to the RS encoder 1000 is assumed to have 239 information symbols followed by 16 zero symbols, i.e., a zero symbol is actually padded at the end of the incoming information sequence instead of the beginning as required by Equation (25), the incoming data needs to be buffered and reformatted to suit Equation (25).

The conversion sequence 1050 for performing buffering and reformatting is shown in FIG. 10(b). Sequence 1050 takes care of the format difference by delaying the processing of the last received symbol to the next cycle. Sequence 1050 works as follows. From the system level, the received symbols 1051 (i.e., u₂₃₈, u₂₃₇, and u₂₃₆) are available during the first cycle (i.e., cycle 0 in FIG. 10(b)). However, the first term of Equation (25) is the following: (0·x¹⁸+u₂₃₈·x¹⁷+u₂₃₇·x¹⁶). This means that the available symbols 1051 are not the appropriate symbols to meet the requirements of Equation (25). Additionally, the next term of Equation (25) is (u₂₃₆·x¹⁸+u₂₃₅·x¹⁷+u₂₃₄·x¹⁶), which means that u₂₃₆ is needed for the second cycle (i.e., cycle 1 of FIG. 10(b)), but not for the first cycle.

To solve this dilemma, encoder 1030 comprises a delay 1055 that delays u₂₃₆ one cycle. Delay 1055 is part of circuit 1070. Additionally, circuit 1070 inputs a zero as the highest order symbol in cycle 0. Thus, in cycle 0, the three-parallel encoder 1000 is used to properly calculate (0·x¹⁸+u₂₃₈·x¹⁷+u₂₃₇·x¹⁶) Three-parallel encoder 1000 passes u₂₃₈ and u₂₃₇, but these are delayed, using delays 1060, so that u₂₃₈, u₂₃₇, and u₂₃₆ arrive unchanged out of the encoder 1030 at the same time (as c₂₅₄, c₂₅₃, and c₂₅₂), which occurs during cycle 1. Also during cycle 1, the information symbols u₂₃₅, u₂₃₄, and u₂₃₃ are received, u₂₃₃ is delayed, and the (u₂₃₆·x¹⁸+u₂₃₅·x¹⁷+u₂₃₄·x¹⁶) calculation is performed. This process continues for 79 cycles, at which time all redundancy symbols have been calculated by the encoder 1030. Note that one redundancy symbol, C₁₅, is output during cycle 79. The rest of the redundancy symbols merely have to be read out of encoder 1030. This is performed by inputting zero symbols into the encoder 1030 for five cycles and retrieving the other 15 redundancy symbols, c₁₄ through co. Circuit 1070 is used to input zeros for the appropriate number of cycles. Optionally, a system (not shown) into which encoder 1030 is placed can input zeros into circuit 1070.

It should be noted that conversion sequence 1050 is performed as described above to reduce complexity. If the last received symbol is not delayed to the next cycle, the complexity of an encoder will increase beyond the complexity shown in FIGS. 10(a) and 10(b). Consequently, encoder 1030 and conversion sequence 1050 reduce complexity and yet still maintain adequate throughput.

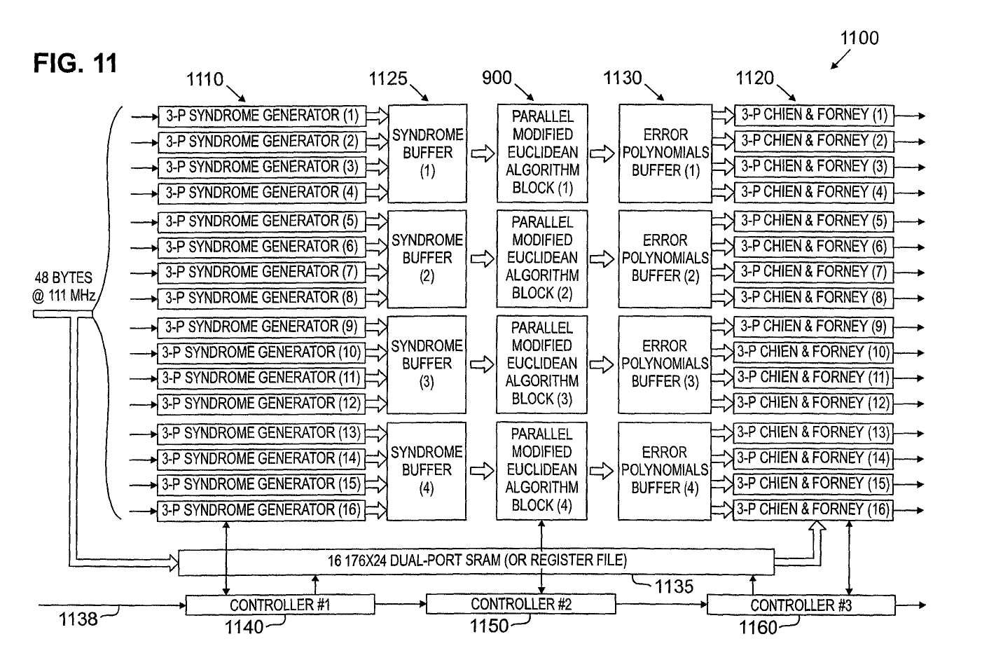

The block diagram of a 16-way interleaved RS decoder 1100 is shown in FIG. 11. The decoder comprises sixteen three-parallel syndrome generators 1110, four key equation solver blocks 900, and sixteen three-parallel Chien's search and Fomey's algorithm blocks 1120 for calculating error locations and error values. Additionally, RS decoder 1100 comprises four syndrome buffers 1125, four error polynomial buffers 1130, a block 1135 of 16 dual-port Static Random Access Memories (SRAMs), each of size 176 by 24, start-of-frame input pulse signal 1138, and three controllers 1140, 1150, and 1160.

The start of a new frame is indicated by the start-of-frame input pulse signal 1138. Each syndrome generator 1110 completes syndrome calculations in 85 cycles and produces 16 syndromes every 85 cycles. Each set of 16 syndromes is generated from one block of 255 symbols. Each syndrome buffer 1125 holds 64 syndromes, wherein each set of 16 syndromes in the 64 syndromes is from one three-parallel syndrome generator 1110. Each syndrome buffer 1125 will then pass one set of 16 syndromes in parallel to one of the key equation solver blocks 900. This occurs every 18 cycles. With the folded parallel implementation shown in FIG. 9, the error locator and error evaluator polynomials for each received block can be found in 16 clock cycles. This indicates that one key equation solver block 900 can be shared among four syndrome generators 1110, because each key equation solver block 900 takes 16 cycles to complete while the syndrome generators 1110 take 85 cycles to complete. Having one solver block 900 shared by four syndrome generators 1110 substantially reduces the overall hardware complexity since the key equation solver block 900 is the most complicated part in RS decoder 1100.

Upon completion of calculating the error locator and error evaluator polynomials for all 16 blocks, these error polynomials are downloaded in parallel into the error polynomials buffers 1130. The error polynomials are collected until all four syndromes have been passed through a key equation solver block 900, and then the error polynomials are downloaded in parallel to the three-parallel Chien's search and Formey's algorithm blocks 1120, where the error locations and error values are found and error corrections are carried out. For three-parallel Chien's search and Forney's algorithm blocks 1120, each block 1120 has one three-parallel version of circuit 500 and one three-parallel version of circuit 600, whose total complexity is about three times that of 500 and 600, respectively. A block 1135 of sixteen dual-port SRAMs of size 176 by 24 is required to buffer the received data for error correction.

As the functional blocks of an RS decoder may be logically divided into three sub-blocks according to the three decoding steps, three control circuits 1140, 1150, 1160 are implemented in RS decoder 1100, one for each decoding step. The controller 1140 for the syndrome generator blocks 1110 is triggered by the start-of-frame input pulse signal 1138, and is responsible for calculating the write address for the SRAMs 1135 as well as generating a pulse to trigger the key equation solver block 900 to download the new syndromes and start computation. The second controller 1150, triggered by a pulse signal from the first controller 1140, is responsible for controlling the time-multiplexing of one key equation solver block 900 among four syndrome generators 1110, and signaling the Chien's search and Fomey's algorithm blocks 1120 to start computation when the error polynomials are available. The second controller 1150 also communicates with control block 990, shown in FIG. 9, to place the key equation solver block 900 into low power mode. The third control block 1160 is triggered by a pulse signal from the second controller 1150 and is responsible for generating control signals for the error correction blocks 1120.

A test is implemented to determine if a group of syndromes are all zeros (i.e., there are no errors in the received block of data). Such testing may be implemented as illustrated in FIG. 2 and, in particular, block 220. If all of the syndromes for one of the three-parallel syndrome generators 1110 are zero, then the rest of the decoder, for this group of syndromes is put into or maintained in low power mode. For instance, if the syndromes for three-parallel syndrome generator (1) 1110 are zero, then the Euclidean algorithm block 900 corresponding to this syndrome generator does not run for this set of syndromes. The Euclidean algorithm block 900 corresponding to three-parallel syndrome generator (1) 1110 will remain in low power mode. If, however, one or more of the syndromes from three-parallel syndrome generator (2) 1110 are not zero, then the Euclidean algorithm block 900 corresponding to this syndrome generator will run. Note that, because the same Euclidean algorithm block 900 is shared amongst three-parallel syndrome generator (1) 1110 through three-parallel syndrome generator (4) 1110, the Euclidean algorithm block 900 is time-multiplexed amongst the four syndrome generators 1110.

There are a variety of locations to test for zero syndromes. For instance, each syndrome buffer 1125 could implement a test to determine if all syndromes for one of the syndrome generators 1110 are zero. Additionally, tests may be made by circuitry (not shown) separate from syndrome generators 1120 and syndrome buffers 1125.

For an input Bit Error Rate (BER) of around 10⁻⁴, an error occurs only 20% of the time. For an input BER of around 10⁻⁵, only the syndrome generator needs to be active most of the time. The three-step, domino-type control circuitry thus mimics the effect of clock gating and allows the decoder to take advantage of this to save power. With three controllers, the RS decoder 1100 has multiple locations at which it can control aspects of the decoder 1100 to save power.

It should be noted that, if all syndromes for a received block are zero, controller 1150 will never start the modified Euclidean algorithm block 900 for this data block. This prevents the modified Euclidean algorithm block 900 from iterating several times and then going into low power mode, and this saves additional power. The iterations would occur because portions of the modified Euclidean algorithm block 900 would not be initialized to zero upon startup.

Note that clock gating may also be used by controllers 1140, 1150, and 1160. This will further reduce power.

The decoder 1100 outputs the decoded data as well as the error correction information, including total number of corrected bits and total number of uncorrectable blocks within one frame. The error information is available two cycles after completion of decoding the current frame. The error correction functions 1120 in the decoder 1100 can be disabled through an input signal. In this case, the decoder 1100 is used as an error monitoring device, and input data are output unaltered after the same decoder-latency delay. This feature allows switching on and off of the error correction functions 1120 based on the BER information. Furthermore, the entire RS decoder 1100 can also be disabled and put into low power mode by first feeding one all-zero frame to the decoder, and then stop sending the start-of-frame input pulse signal. These steps reduce the switching activity in the decoder 1100 to a minimum and hence also reduce the power consumption.

The techniques used to design this low complexity, low power RS decoder 1100 can be summarized as follows: (1) selection of low complexity Galois field arithmetic units, i.e., multiplier and composite-basis divider; (2) choice of the appropriate decoding algorithm, i.e., the modified Euclidean algorithm, and design of the low power folded parallel architecture for this algorithm; (3) sub-structure sharing, e.g., sharing of one key equation solver block among four syndrome generators; and (4) domino-type control circuitry that allows powering down the key equation solver block and the Chien's search and Fomey's algorithm blocks in case of no errors or when the actual number of errors are less than a maximum error correction capability of the code.

### Detection of Uncorrectable Errors

With a hard-decision algebraic decoding scheme, an RS(255,239) code is unable to correct more than eight symbol errors. When these uncorrectable errors occur, a typical decoding process could either generate a non-code-word output sequence, or “correct” the received sequence to another code word. The former case is referred to as a decoding failure, and the latter is called a decoding error.

In both cases, the decoder adds additional errors to the received sequence. Hence, it is desirable for the decoder to detect the uncorrectable blocks and output the incoming sequence unaltered. Generally, decoder errors are hard to detect. For RS codes over GF(2^{m}) with relatively large values of m and t, it is very likely that more than 90 percent of the cases decoding of an uncorrectable block result in detectable decoding failures. In particular, the RS(255,239) code over GF(2⁸) can detect almost all uncorrectable errors.

Detection of decoding failure can be performed by re-calculating the syndromes of the decoder output sequence. A failure is then detected if not all the syndrome values equal zero. On the other hand, detection of decoding failure can also be performed during the Chien's search. The current block is flagged as uncorrectable if either (1) during the Chien's search, it is found that the error locator polynomial Λ(x) has multiple roots; or (2) upon completion of Chien's search, the total number of symbol errors found is less than the degree of Λ(x). Since the Chien's search covers all the elements in GF(2^{m}), this indicates that not all the roots of Λ(x) are in the Galois field GF(2⁸), which can only happen when more than eight symbol errors occur.

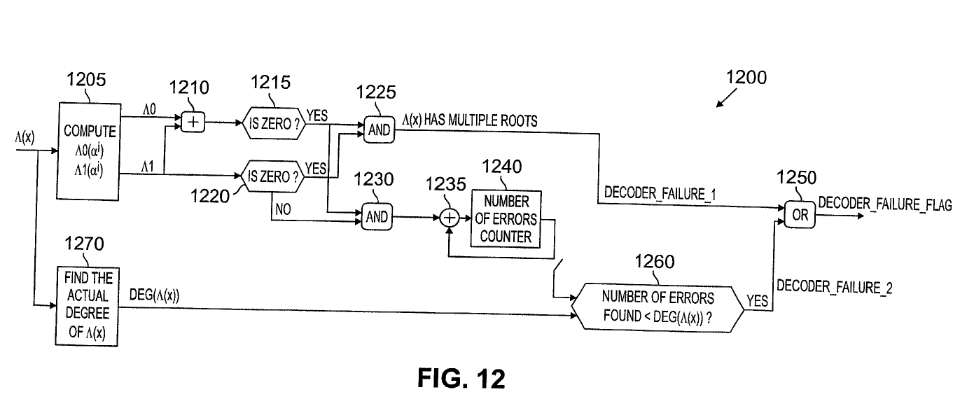

Since the degree of Λ(x) is no greater than eight, this scheme requires only a four-bit accumulator and a four-bit comparator, which is much simpler than re-computing the syndromes. A modified Chien's search circuit 1200 is shown in FIG. 12. This circuit comprises a computation block 1205, an adder 1210, two zero decision blocks 1215 and 1220, two ANDs 1225 and 1230, an adder 1235, an error counter 1240, an OR 1250, a degree decision block 1260, and a degree computation block 1270. Normally, a Chien's search circuit would contain computation block 1205, adder 1210, two zero decision blocks 1215 and 1220, AND 1230, adder 1235, and error counter 1240. The devices added to perform the modified Chien's search are the AND 1225, adder 1225, OR 1250, degree decision block 1260, and degree computation block 1270.

As described above, there are two ways for modified Chien's search circuit 1200 to report an error. If both Λ0+Λ1 and Λ1 are zero, then Λ(x) has multiple roots. This causes an error. Additionally, if degree decision block 1260 determines that the number of errors is less than the deg(Λ(x)), then an error is flagged. Degree computation block 1270 finds the leading nonzero coefficient of Λ(x) to determine its degree, and the degree decision block 1260 is a four-bit comparator that compares the number of errors with the deg(Λ(x)).

It is worth mentioning that the latter simplified scheme only covers some sufficient condition of decoding failure, and it is possible to miss flagging some uncorrectable blocks. Simulation results show that for RS codes over smaller Galois fields and with smaller value of t, the latter scheme is inferior; however, for RS(255,239) code, it is as robust as the syndrome based approach.

### Another Exemplary Encoder and Decoder

This section describes an exemplary architecture and implementation of an RS FEC device residing in an optical networking interface device. This optical networking interface device supports quad 2.488 Gb/s and single 9.952 Gb/s system payload rates. It implements RS(255,239) FEC over 16-way interleaved frames in quad 2.488 Gb/s rate, and 16/64-way interleaved frames in single 9.952 Gb/s payload rate (2.666 Gb/s and 10.663 Gb/s line rate, respectively, taking into account the FEC overhead).

Moreover, the decoder should be able to operate in any of the following four modes: (1) decoder enable (i.e., decode and carry out error correction); (2) monitoring mode (i.e., decode, calculate error information without error correction); (3) decoder disabled and output incoming data after decoder-latency delay mode; and (4) decoder disabled and output incoming data without delay mode. As the payload rate in this example is much lower than in the previously described example, a challenge here is to come up with an architecture that supports all these complicated mode requirements with the smallest hardware complexity.

A 16-way interleaved frame at a single 10 Gb/s payload rate could be designed with 16 encoders and 16 decoders operating at 83 MHz clock rate. Likewise, a 64-way interleaved frame at single 10 Gb/s payload rate and a 16-way interleaved frame at quad 2.5 Gb/s rate could be designed with 64 encoders and 64 decoders operating at 21 MHz clock rate. Instead of implementing 64 separate encoders and decoders to cover the worst case, a slow-down and interleaving scheme as well as resource sharing are applied. These allow use of 16 serial encoders and decoders operating at 83 MHz to support all three system interleaving and clock rate schemes.

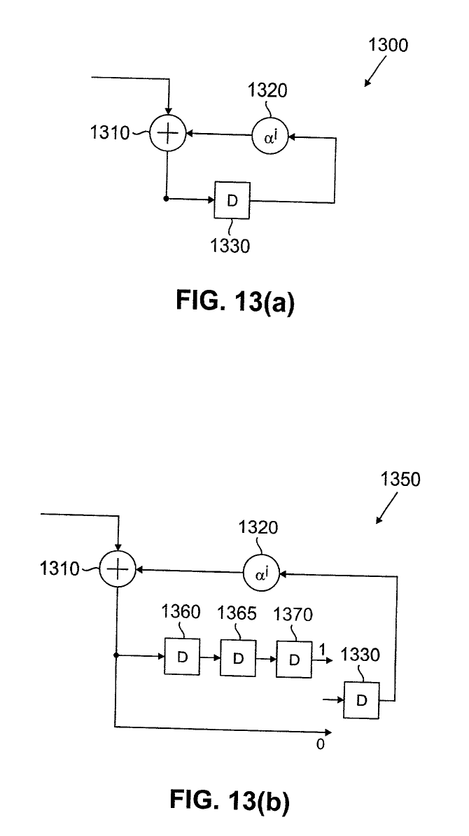

The slow-down and interleaving technique can be explained using one syndrome generator as an example. FIG. 13(a) shows a circuit 1300 for computing one syndrome. Circuit 1300 comprises an adder 1310, a constant multiplier 1320, and a delay 1330. Now replace the single delay element by four delay elements and insert a multiplexer (MUX) as shown in FIG. 13(b). FIG. 13(b) shows a circuit 1350 that is essentially circuit 1300 but with an additional three delays 1360, 1365, 1370, and a MUX 1375. This circuit 1350 operates at the same clock rate as does the circuit 1300. When the MUX 1375 is switched to position 0, the circuit 1350 is essentially the same as the circuit in FIG. 13(a). When the MUX 1375 is switched to position 1, the throughput rate of the original computation is slowed down four times. On the other hand, four syndrome computations (syndrome Sᵢ for four different received blocks) can be computed simultaneously in a interleaved manner, provided that the symbols of these four received blocks are already interleaved as they enter the syndrome generator as follows:

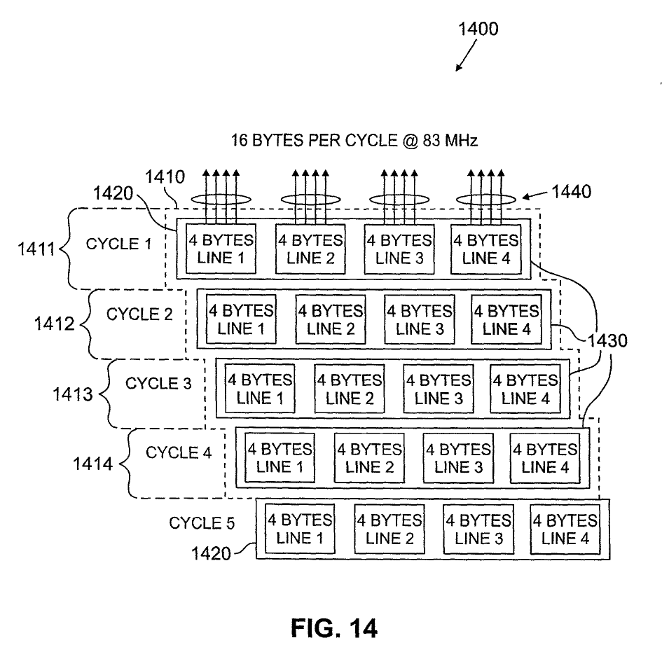

r₂₅₄⁽¹⁾, r₂₅₄⁽²⁾, r₂₅₄⁽³⁾, r₂₅₄⁽⁴⁾, r₂₅₃⁽¹⁾, r₂₅₃⁽²⁾, r₂₅₃⁽³⁾, r₂₅₃⁽⁴⁾, . . . , r₀⁽¹⁾, r₀⁽²⁾, r₀⁽³⁾, r₀⁽⁴⁾,

where rⱼ^{l} is the j-th symbol from the l-th received block. This technique is applied to the RS encoder, syndrome generator, and Chien's search and Fomey's algorithm blocks. The input data format of both encoder and decoder in the quad 2.5 Gb/s and 64-way interleaved 10 Gb/s frame is shown in FIG. 14, where the 64 code blocks 1410 in each super frame are first divided into four separate groups 1411, 1412, 1413, and 1414, and symbols of the 16 blocks in each group are input to an encoder/decoder four at a time. Hence, the consecutive symbols from the same code block are input every four cycles, as illustrated in the figure by reference numeral 1420. This input occurs every four cycles at a rate of 21 MHz. Reference numeral 1440 indicates that four symbol generators share one key equation solving block. Also, reference numeral 1430 indicates that data in these four consecutive cycles belong to different code words and can be computed using the same slowed encoder/decoder in an interleaved fashion.

As it is required in this example that the FEC device should be able to operate in 4 different clock domains in the quad 2.5 Gb/s mode, the resource sharing in the decoder is restrained to be among four decoders in the same clock domain only. The decoder is partitioned into four slices, each containing four syndrome generators, one shared key equation solver block, four error correction blocks, and three shared controller blocks. Each slice can decode four code blocks in parallel, or 16 code blocks in an interleaved fashion.

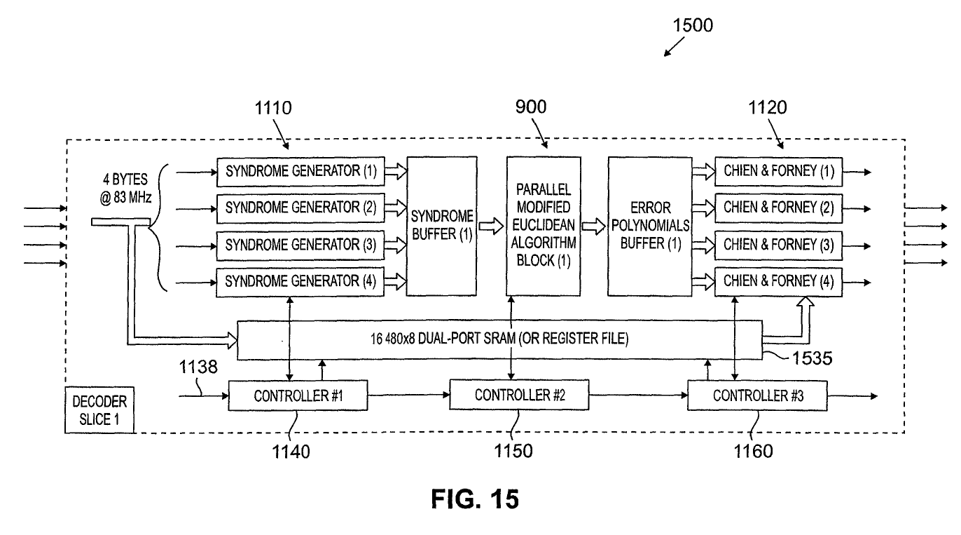

One slice of an entire decoder is shown in FIG. 15. Slice 1500 comprises four syndrome generators 1110, one key equation solver block 900, and four Chien's search and Forney's algorithm blocks 1120 for calculating error locations and error values. Additionally, slice 1500 comprises one syndrome buffer 1125, one error polynomials buffer 1130, a block 1535 of four dual-port SRAMs, each of size 480 by 8, start-of-frame input pulse signal 1138, and three controllers 1140, 1150, and 1160. Most of these blocks have been described in reference to FIG. 11.

By implementing a circuit such as that shown in FIG. 13(b) in the RS encoder (not shown), syndrome generator 1110, and Chien's search and Fomey's algorithm block 1120, the system of FIG. 15 can operate in several schemes. In one scheme, it produces 16 bytes of decoded and corrected data at a speed of 83 MHz. In a second scheme, it produces 64 bytes of decoded and corrected data at a speed, for an entire interleaved block, of 21 MHz. In other words, in this second scheme, it actually produces 16 bytes of data at a speed of 83 MHz, but interleaving means that symbols for a particular code block are output at a speed of 21 MHz.

With the slow-down, interleaving and resource sharing, the hardware required for the decoding operation itself has been reduced dramatically. However, the registers and memory requirements are not reduced and are about 64 times that of a single decoder. As a result, the device complexity is dominated by flip-flops and SRAMs. Nevertheless, with this architecture, the overall decoder complexity is reduced by about a factor of one-half compared with a single decoder solely designed to decode the worst-case scenario of a 64-way interleaved frame at single 10 Gb/s payload rate.

A salient feature of this exemplary RS decoder is that it can disable the error correction operation automatically when uncorrectable errors are detected, hence preventing the decoder from further corrupting the data. Instead of performing “on-the-fly” error correction, this exemplary decoder first uses Chien's search and Forney's algorithm to calculate error locations and error values. Upon completion, it flags whether or not the current block is correctable using the scheme presented in reference to FIG. 12. Error correction is then carried out sequentially on the buffered received data if the current block is correctable. Otherwise, the incoming data is output unaltered. While the original on-the-fly error correction has literally zero latency, the delayed error correction adds n-cycle additional delays to the decoder if a serial implementation of Chien's search algorithm is used. This also increases the size of the SRAM used to buffer the incoming data. A two-parallel Chien's search block is implemented in this design to better exploit the trade-off between the complexity of the Chien's search block and the additional memory storage requirement.

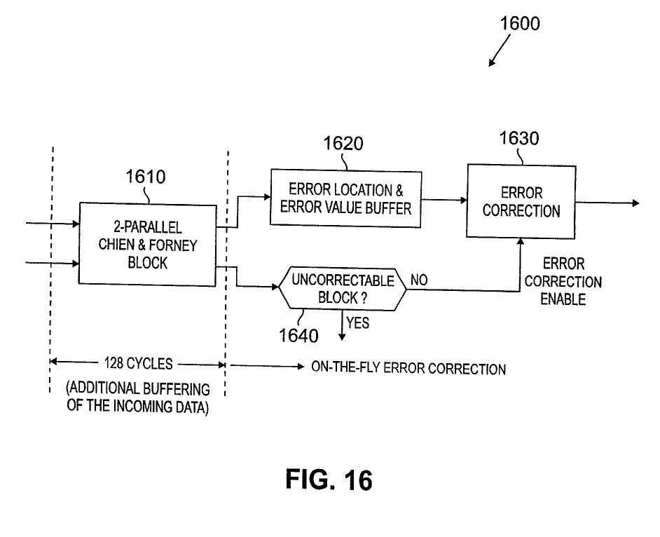

The entire error correction block is illustrated in FIG. 16. Error correction block 1600 comprises a two-parallel Chien and Forney block 1610, an error location and error value buffer 1620, an error correction block 1630, and an uncorrectable decision block 1640. If the block is correctable (block 1640=NO), then error correction is performed in block 1630. If the block is not correctable (block 1640=YES), a signal is output that will cause the received data to pass through unaltered. This system prevents the decoder from introducing more errors than are already present in the received symbols.

Although the present invention has been illustrated herein using RS codes, those skilled in the art will recognize that the described techniques are applicable to other types of codes and code rates. For example, the present invention can be used, in general, for decoding Bose-Chaudhuri-Hochquenghem (BCH) codes of various rates. As is known in the art, an RS code is a special type of non-binary BCH code.

It is to be understood that the embodiments and variations shown and described herein are merely illustrative of the principles of this invention and that various modifications may be implemented by those skilled in the art without departing from the scope and spirit of the invention.

We claim:

1. A method performed in an error correction system, the method comprising the steps of:
determining if an actual number of errors is less than a maximum error correction capability; and
reducing power consumption in a decoder of the error correction system when the actual number of errors is less than the maximum error correction capability.

2. The method of claim 1, wherein the step of reducing power consumption further comprises the step of gating one or more clocks coupled to the error correction system.

3. The method of claim 1, further comprising the step of providing a plurality of intermediate polynomials, and wherein the step of reducing power consumption in the error correction system when the actual number of errors is less than the maximum error correction capability further comprises the step of determining if a degree of at least one of the intermediate polynomials is less than a predetermined degree.

4. The method of claim 3, wherein one intermediate polynomial is R(x), wherein one intermediate polynomial is F(x), wherein one intermediate polynomial is Q(x), wherein one intermediate polynomial is G(x), and wherein the step of determining if a degree of at least one of the intermediate polynomials is less than a predetermined degree further comprises the step of determining if a degree of either R(x) or Q(x) is less than a predetermined degree.

5. The method of claim 3, further comprising the step of providing, in the decoder, a plurality of intermediate polynomial elements and a calculation circuit coupled to the intermediate polynomial elements, each intermediate polynomial element containing coefficients of one of the intermediate polynomials, and wherein the step of reducing power consumption in a decoder of the error correction system when the actual number of errors is less than the maximum error correction capability further comprises the step of placing a predetermined state into each of the intermediate polynomials, the predetermined state selected to reduce switching of the calculation circuit.

6. The method of claim 5, wherein the predetermined state is zero.

7. The method of claim 1, further comprising the steps of:
determining a plurality of syndromes;
determining if all of the syndromes have a predetermined value; and
reducing power consumption of the decoder of the error correction system when all of the syndromes have the predetermined value.

8. The method of claim 7, wherein the predetermined value for each syndrome is zero.

9. The method of claim 7, wherein the method further comprises the steps of providing a key equation solving device in the decoder, and providing a plurality of syndrome generators, each of the syndrome generators determining one of the syndromes, wherein the key equation solving device is coupled to each of the syndrome generators, and wherein the step of reducing power consumption of the decoder of the error correction system when all syndromes have the predetermined value further comprises the step of not enabling the key equation solving device when all of the syndromes have the predetermined value.

10. The method of claim 9, further comprising the step of calculating at least one error polynomial when at least one syndrome does not have the predetermined value.

11. A decoder comprising:
a key equation determination device comprising:
a plurality of registers, each register adapted to hold coefficients of an intermediate polynomial;
a calculation circuit adapted to calculate new values of the coefficients in the registers in order to determine two error polynomials; and
a control circuit coupled to at least one of the registers, the control circuit adapted to determine when an actual number of errors is less than a maximum error correction capability and to place the calculation circuit into a low power mode when the actual number of errors is less than the maximum error correction capability, the control circuit using at least one of the registers when determining the actual number of errors.

12. The decoder of claim 11, wherein for the key equation determination device:
the plurality of registers are four registers;
the control circuit determines when an actual number of errors is less than a maximum error correction capability by determining if a degree of at least one of polynomials that correspond to a register is less than a predetermined degree; and
the control circuit places the calculation circuit into a low power configuration by providing predetermined inputs to the registers.

13. The decoder of claim 12, wherein for the key equation determination device:
the predetermined inputs are zeros;
each register holds coefficients for one of a polynomial R(x), a polynomial F(x), a polynomial Q(x), and a polynomial G(x); and
the key equation determination device further comprises four operating modes, a first mode that is performed by the calculation circuit and that calculates new values of the coefficients in the registers in order to determine two error polynomials, a second mode that reduces a degree of R(x), a third mode that reduces a degree of Q(x), and a fourth mode that inputs zeros to the registers.

14. The decoder of claim 13, wherein:
the key equation determination device further comprises four multiplexers;
the key equation determination device further comprises three additional circuits that are coupled to outputs of the registers and to inputs of the four multiplexers;
each of the second, third, and fourth operating modes is performed by one of the additional circuits;
the calculation circuit and the three additional circuits operate in parallel;
outputs of the multiplexers are coupled to inputs of the registers; and
the control circuit selects, during each cycle, an output of one of the four multiplexers, thereby selecting an output of one of the operating modes.

15. The decoder of claim 14, wherein the control circuit selects an output of the mode according to the following:
the output of the first mode when both a leading coefficient of R(x) and a leading coefficient of Q(x) are nonzero;
the output of the second mode when the leading coefficient of R(x) is zero;
the output of the third mode when the leading coefficient of Q(x) is zero; and
the output of the fourth mode when the degree of R(x) is less than a predetermined value or when the degree of Q(x) is less than a predetermined value.

16. The decoder of claim 11 further comprising:
a plurality of syndrome generators coupled to the key equation determination device, each syndrome generator generating a syndrome in a predetermined number of cycles; and
wherein the key equation determination device accepts a syndrome from each of the syndrome generators and determines the two error polynomials for each syndrome, wherein the key equation determination device is capable of determining all of the error polynomials for all of the syndrome generators during a number of cycles that is less than the predetermined number of cycles.

17. The decoder of claim 16, further comprising a syndrome buffer placed between and coupled to the plurality of syndrome generators and the key equation determination device, the syndrome buffer accepting each syndrome.

18. The decoder of claim 17, further comprising a second control circuit, the second control circuit coupled to the syndrome buffer and to the control circuit of the key equation determination device through at least one control signal, the second control circuit operating the at least one control signal to cause one of the syndromes in the syndrome buffer to be transferred to the key equation determination device and to cause the key equation determination device to determine the two error polynomials for the one syndrome, wherein each of the syndromes are serially transferred to the key equation determination device.

19. The decoder of claim 16, further comprising:
a syndrome testing device, the syndrome testing device testing all of the syndromes to determine if each syndrome has a predetermined value; and
a second control circuit coupled to the syndrome testing device and to the control circuit of the key equation determination device, the second control circuit placing the key equation determination device in a low power configuration when all syndromes have the predetermined value.

20. The decoder of claim 19, wherein the predetermined value for each syndrome is zero.

21. The decoder of claim 19, wherein the second control circuit comprises a control signal coupled to the control circuit of the key equation determination device, and wherein the second control circuit places the key equation determination device in low power configuration by placing the control signal in predetermined state wherein the key equation determination device does not perform calculations to determine the at least one error polynomial.

22. The decoder of claim 19, wherein the second control circuit comprises first and second portions, wherein the first portion is coupled to the syndrome testing device and to the second portion, and wherein the second portion is coupled to the control circuit of the key equation determination device, the first portion directing the second portion to place the key equation determination device in the low power configuration when each syndrome is the predetermined value.

23. A decoder comprising:
means for determining a key equation, comprising:
a plurality of registers, each register adapted to hold coefficients of an intermediate polynomial;
means for calculating new values of the coefficients in the registers in order to determine two error polynomials; and
means for determining when an actual number of errors is less than a maximum error correction capability and to place the means for calculating into a low power mode when the actual number of errors is less than the maximum error correction capability, the means for determining using at least one of the registers when determining the actual number of errors.

24. The decoder of claim 23, further comprising:
a plurality of syndrome generators coupled to means for determining the key equation, each syndrome generator generating a syndrome in a predetermined number of cycles; and
wherein the means for determining a key equation accepts a syndrome from each of the syndrome generators and determines the two error polynomials for each syndrome, wherein the means for determining a key equation is capable of determining all of the error polynomials for all of the syndrome generators during a number of cycles that is less than the predetermined number of cycles.

25. A decoder comprising:
means for determining if an actual number of errors is less than a maximum error correction capability; and
means for reducing power consumption in a decoder of an error correction system when the actual number of errors is less than the maximum error correction capability.

26. An integrated circuit comprising:
means for determining if an actual number of errors is less than a maximum error correction capability; and
means for reducing power consumption in a decoder of an error correction system when the actual number of errors is less than the maximum error correction capability.

27. An encoder adapted to accept a first, a second, and a third input per cycle, the encoder comprising:
a three-parallel encoder adapted to accept a first, a second, and a third three-parallel input per cycle and adapted to determine a plurality of redundant output symbols after a predetermined number of cycles;
a circuit adapted to place a zero on the first three-parallel input during a first cycle of the three-parallel encoder and adapted to input zeros to the first, second, and third three-parallel inputs after a second predetermined number of cycles;
a first delay element coupled to the third input, an output of the first delay element coupled to the third three-parallel input;
a first additional delay element coupled to the second three-parallel input;
a second additional delay element coupled to the third three-parallel input; and
wherein the first input is coupled to the second three-parallel input and the second input is coupled to the third three-parallel input, and wherein the first, second, and third inputs are output by the encoder one cycle after being input to the encoder.
